(19) United States
(12) Patent Application Publication
(10) Pub. No.: US 2007/0214634 A1
(43) Pub. Date: Sep. 20, 2007

(54) Method of manufacturing a magnetic head

(75) Inventor: Masanori Yaguchi, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/644,826

(22) Filed: Dec. 26, 2006

(30) Foreign Application Priority Data
Mar. 17, 2006 (JP) 2006-73628

(51) Int. Cl. G11B 5/127; G01R 31/28; H01R 43/00

(52) U.S. Cl. 29/603.09; 29/854; 29/593

(57) ABSTRACT

A method of manufacturing a magnetic head carries out a testing step, in which the magnetic head is heated, quickly and with a low operation cost and therefore can reduce delays in the manufacturing process and the need to repeat the manufacturing process. The method includes a row bar holding step of holding at least one surface in a lengthwise direction of a row bar using a holding jig with a lower thermal expansion coefficient than the row bar, a wire bonding step of connecting, using wires, connection terminals of respective magnetic heads on the row bar and test terminals for electrically connecting the connection terminals for test purposes, a heating step of heating the row bar, and a functional characteristic testing step of testing functional characteristics of the respective magnetic heads via the test terminals and the wires.

### BACKGROUND OF THE INVENTION

1. Field of the Invention

The present invention relates to a method of manufacturing a magnetic head that includes a testing step that heats the magnetic head and tests the functional characteristics of the magnetic head.

2. Related Art

It is known that the electromagnetic conversion characteristics of an MR element of a magnetic head used in a magnetic disk apparatus degrade over time, so that in due time the MR element will reach the end of its operating life.

In addition, the rate at which the electromagnetic conversion characteristics degrade over time fluctuates between magnetic heads or manufacturing lots of magnetic heads due to fluctuations in the manufacturing quality of the magnetic heads.

For this reason, sampling tests have been conventionally carried out for magnetic heads to grasp the electromagnetic conversion characteristics of respective magnetic heads (or respective manufacturing lots) so that magnetic heads that have been determined to not satisfy a predetermined standard regarding the length of the operating life can be rejected and therefore excluded from the products that are shipped.

As one example, a predetermined number of magnetic heads may be extracted from each manufacturing lot of magnetic heads as samples and an operation that accelerates the degradation of the MR elements may be carried out on such samples to test whether there are any magnetic heads (defective magnetic heads) that have degraded faster than a predetermined standard and reached the end of their operating lives. If defective magnetic heads are specified and the defects are caused by a problem that is common to the manufacturing lot to which the magnetic heads belong, as one example, all of the magnetic heads belonging to such manufacturing lot may be discarded as defective products.

Patent Document 1 discloses a method of testing the electromagnetic conversion characteristics of the MR element of a magnetic head by heating the magnetic head to accelerate the degradation of the MR element of the magnetic head and also applying a magnetic field to the magnetic head.

In the technique disclosed in Patent Document 1, the magnetic head is set in a constant temperature oven and heated inside the constant temperature oven, an alternating magnetic field is applied to the magnetic head, and the electromagnetic conversion characteristics such as the magnetic resistance characteristics and the electrical resistance of the MR element of the magnetic head are tested.

Aside from the method of heating a magnetic head via a constant temperature oven or the like as in the technique disclosed in Patent Document 1, as shown in FIG. 4, there is also a conventional method where a magnetic head 92 is heated by incorporating the magnetic head 92 in an HGA (head gimbal assembly) 90, pressing the magnetic head 92 part of the HGA 90 onto a heating plate 96 using an elastic force produced by a suspension 94, and heating the heating plate 96. By applying a magnetic field to the magnetic head 92 using poles 98a, 98b of an electromagnet disposed on both sides of the heating plate 96, the electromagnetic conversion characteristics of the MR element of the magnetic head 92 are tested via a wiring pattern provided on the HGA 90.

### Patent Document 1

Japanese Laid-Open Patent Publication No. 2001-14622 However, in the testing step of a magnetic head disclosed in Patent Document 1, in addition to providing a constant temperature oven that can withstand a high temperature, the wiring and the like used to electrically connect the magnetic head need to be constructed so as to withstand high temperatures, resulting in the problem of increased equipment cost.

Also, since the magnetic head is susceptible to deformation due to high temperatures, there is the problem that if the magnetic head is electrically connected using a contact probe or the like that contacts the connection terminals of the magnetic head, poor electrical contact can result from the magnetic head deforming.

On the other hand, with a method where the magnetic head is tested after being incorporated in an HGA, there are the merits that equipment such as a constant temperature oven is not required, resulting in a comparatively low equipment cost, and that deformation of the magnetic head due to the heat required to attach the magnetic head to a metal suspension can be suppressed.

However, there is the problem of the time and operation cost of incorporating a magnetic head in an HGA. In particular, if the testing is time-consuming, the judgment of whether the manufacturing lot to which the magnetic head belongs is defective or non-defective will be delayed, resulting in the problem of the manufacturing process being susceptible to delays and having to be repeated, thereby lowering the manufacturing efficiency.

### SUMMARY OF THE INVENTION

The present invention was conceived in view of the problem described above and it is a principal object of the present invention to provide a method of manufacturing a magnetic head that carries out a testing step for a magnetic head that heats the magnetic head quickly and with a low operation cost and therefore can reduce delays in the manufacturing process and the need to repeat the manufacturing process. It is a further object of the present invention to provide a method of manufacturing a magnetic head including a testing step that suppresses deformation of the magnetic head due to heat and can electrically connect to connection terminals of the magnetic head more stably.

To achieve the stated objects, a method of manufacturing a magnetic head according to the present invention includes a testing step that heats the magnetic head and tests the functional characteristics of the magnetic head, wherein the testing step includes: a row bar holding step of holding at least one surface in a lengthwise direction of a row bar cut out from a wafer using a holding jig with a lower thermal expansion coefficient than the row bar; a wire bonding step of connecting, via wires, connection terminals of respective magnetic heads on the row bar and test terminals for electrically connecting the connection terminals for test purposes; a heating step of heating the row bar; and a functional characteristic testing step of testing functional characteristics of the respective magnetic heads via the test terminals and the wires.

By doing so, since the heating step and the functional characteristic testing step are carried out in a state where a row bar has been cut out from a wafer, compared to a method where tests are carried out after incorporating a magnetic head in an HGA, it is possible to suppress the time and operation cost of tests. In addition, since at least one surface in the lengthwise direction of the row bar is held using a holding jig with a lower thermal expansion coefficient than the row bar, it is difficult for the row bar (magnetic heads) to deform due to heat and since the connection terminals of the magnetic head are electrically connected using wires, even if the magnetic heads deform due to heat, the wires will deform in accordance with the deformation of the magnetic heads, thereby avoiding problems such as poor electrical contact.

In addition, the row bar holding step may hold the row bar on the holding jig so that a formation surface of the connection terminals on the row bar is exposed to one end surface of the holding jig and is substantially parallel to the end surface, and the test terminals may be provided on the end surface.

According to the above construction, since the formation surface of the connection terminals of the row bar (the magnetic heads) is exposed substantially parallel to the end surface of the holding jig on which the test terminals are provided, it is easy to connect the wires in the wire bonding step within a substantially parallel plane.

In addition, the test terminals may be provided on a flexible printed circuit board disposed across an outer surface of the holding jig.

According to the above construction, the test terminals can be favorably provided on the holding jig. Also, by replacing the flexible printed circuit board, it is possible to easily replace the test terminals and to change the arrangement of the test terminals in accordance with the specification of the magnetic heads (the row bar).

A cutaway part, which matches an outer shape of the row bar, may be formed in an edge part of the end surface of the holding jig, and the row bar holding step may hold the row bar inside the cutaway part.

According to the above construction, it is possible to hold the row bar more firmly so that the row bar does not become displaced.

The row bar holding step may hold the row bar on the holding jig by adhesion.

According to the above construction, it is possible to hold the row bar more firmly so that the row bar does not become displaced.

Also, the holding jig may be made of metal.

According to the above construction, deformation of the holding jig due to heat becomes difficult, and therefore deformation of the row bar can be suppressed more favorably. It is also possible to make the holding jig more durable.

The heating step may be carried out by placing an opposite surface to the one surface in a lengthwise direction of a row bar in contact with a heating plate and heating the heating plate.

According to the above construction, compared to a method where a constant temperature oven or the like is provided, it is possible to suppress the equipment cost and the testing step can be carried out easily. Also, by sandwiching the row bar between the holding jig and the heating plate, deformation of the row bar due to heat can be suppressed more favorably.

Also, in the functional characteristic testing step, a magnetic field may be applied to the row bar and electromagnetic conversion characteristics of MR elements of the respective magnetic heads may be tested.

According to the above construction, it is possible to favorably test the electromagnetic conversion characteristics of the MR elements of the magnetic heads.

With the method of manufacturing a magnetic head according to the present invention, a testing step of a magnetic head that heats the magnetic head can be carried out quickly and with a low operation cost and therefore delays in the manufacturing process and the need to repeat the manufacturing process can be reduced. Also, in the heating step and the functional characteristic testing step, deformation of the magnetic head due to heat can be suppressed and the connection terminals of the magnetic head can be electrically connected more stably.

### BRIEF DESCRIPTION OF THE DRAWINGS

The aforementioned and other objects and advantages of the present invention will become apparent to those skilled in the art upon reading and understanding the following detailed description with reference to the accompanying drawings.

In the drawings:

FIG. 1 is a perspective view showing a state where a row bar is held on a holding jig;

FIG. 2 is a view showing a state where the row bar has been placed in contact with a heating plate;

FIG. 3 is a view showing a state where a magnetic field is applied to the row bar; and

FIG. 4 is a diagram useful in explaining a conventional method of testing a magnetic head.

### DESCRIPTION OF THE PREFERRED EMBODIMENTS

Preferred embodiments of a method of manufacturing a magnetic head according to the present invention will now be described.

In the manufacturing process of a magnetic head, steps such as laminating a magnetic material onto the surface of an Al₂O₃—TiC wafer are carried out to form a plurality of magnetic heads that respectively have MR elements in columns and rows on the wafer. After connection terminals of the respective magnetic heads have been formed on the surface of the wafer, the wafer is cut up to separate rows of the magnetic heads. The strip-like bodies that have been cut out from the wafer and on which a plurality of magnetic heads are aligned in a row are normally referred to as “row bars” by technicians in the industry.

In the present embodiment, one or a number out of the plurality of row bars cut out from a single wafer are used as samples, degradation of the MR elements is accelerated by heating, and the functional characteristics of the MR elements are tested. Magnetic heads whose functional characteristics have been judged to not satisfy a predetermined standard are rejected and excluded from the products that are shipped. That is, it is tested whether there are any magnetic heads (defective magnetic heads) where the MR elements have degraded faster than a predetermined standard and reached the end of their operating lives. If defective magnetic heads are specified and the defect is caused by a problem that is common to the manufacturing lot to which the magnetic heads belong, measures such as discarding all of the magnetic heads belonging to such manufacturing lot are taken.

An embodiment of the method of manufacturing a magnetic head according to the present invention will now be described.

In the testing step in the method of manufacturing a magnetic head according to the present embodiment, first, a row bar holding step is carried out where a row bar is held on a holding jig.

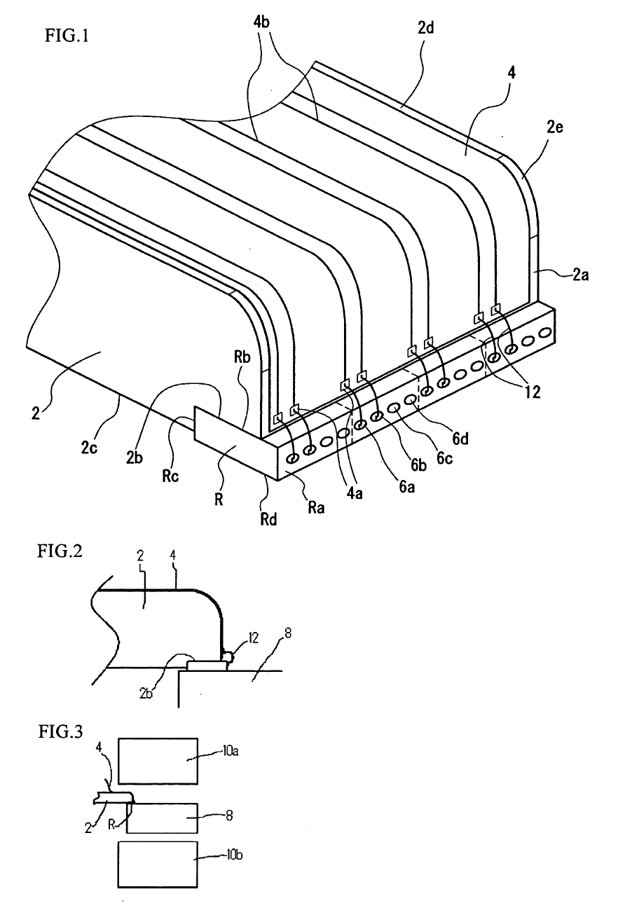

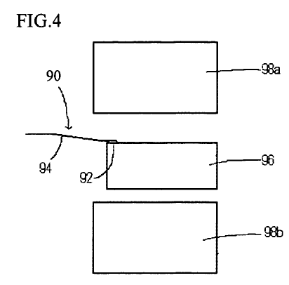

FIG. 1 is a perspective view useful in explaining a state where a row bar R is held on a holding jig 2.

The holding jig 2 is made of metal (for example, iron or an iron alloy) with a lower thermal expansion coefficient than the row bar R. A cutaway part 2b that matches the outer shape of the row bar R is formed in an edge part of one end surface 2a of the holding jig 2. As shown in FIG. 1, the cutaway part 2b is provided in an edge part of the end surface 2a of the holding jig 2 and a surface 2c that is parallel to the end surface 2a so as to be open to both surfaces and is formed in a stepped shape so as to match both an attachment surface Rb (i.e., an opposite surface to an ABS surface Rd) of the row bar R (the magnetic heads H) that is attached to a gimbal part of the suspension and an opposite surface Rc to a surface Ra on which connection terminals 6a to 6d of the row bar R (the magnetic heads H) are formed.

Note that in FIG. 1, the broken lines drawn on the row bar R indicate the boundaries between the magnetic heads H included in the row bar R (that is, the cutting positions when the magnetic heads H are cut out from the row bar R).

In this row bar holding step, the row bar R is held on the holding jig 2 by adhesion in a state where the attachment surface Rb and the opposite surface Rc to the formation surface Ra of the connection terminals 6a to 6d have been aligned with the cutaway part 2b. That is, the row bar R is held inside the cutaway part 2b with two surfaces Rb, Rc thereof in the lengthwise direction adhering to surfaces of the cutaway part 2b of the holding jig 2. By doing so, the formation surface Ra of the connection terminals 6a to 6d on the row bar R becomes exposed in parallel with the end surface 2a of the holding jig 2 on the same side as the end surface 2a.

A flexible printed circuit board 4, which extends from above the end surface 2a onto an opposite surface 2d to the surface 2c, is provided on the surface of the holding jig 2. The flexible printed circuit board 4 is produced by providing a conductive pattern made of copper or the like on a thin polyimide substrate.

A corner part 2e of the holding jig 2 between the end surface 2a and the surface 2c is formed as a continuous curved surface so that the flexible printed circuit board 4 can bend smoothly.

Test terminals 4a are provided on the flexible printed circuit board 4 so as to be located above the end surface 2a and near the cutaway part 2b. The test terminals 4a are provided so as to respectively correspond to read signal connection terminals (that is, connection terminals corresponding to the MR element) 6a, 6b of the respective magnetic heads H included in the row bar R (the connection terminals 6c, 6d are write signal connection terminals). Note that in the present embodiment, to test only the electromagnetic conversion characteristics of the MR elements, the test terminals 4a are provided corresponding to only the read signal connection terminals 6a, 6b, but when the functional characteristics on the write side are tested, test terminals may also be provided at positions corresponding to the write signal connection terminals 6c, 6d.

Wires 4b that are connected to the test terminals 4a are provided on the flexible printed circuit board 4.

The test terminals 4a and the wires 4b are provided as the conductive pattern mentioned above.

The other ends of the wires 4b to the test terminals 4a are connected to a test circuit for the electromagnetic conversion characteristics, not shown.

After the row bar holding step described above, a wire bonding step that connects the read signal connection terminals 6a, 6b of the magnetic heads H on the row bar R used during testing and the test terminals 4a is carried out using wires 12.

After the wire bonding step, a heating step that heats the row bar R held on the holding jig 2 is carried out. By heating the row bar R, as described above, degradation of the MR elements of the magnetic heads H included in the row bar R is accelerated.

As shown in FIG. 2, the heating step is carried out by placing the ABS surface Rd (an opposite surface to the attachment surface Rb attached to the holding jig 2) of the row bar R in contact with a heating plate 8 and heating the heating plate 8.

Following the heating step, a functional characteristics testing step that tests the functional characteristics of the respective magnetic heads H is carried out via the test terminals 4a and the wires 12. In the present embodiment, as the functional characteristics testing step, a magnetic field is applied to the row bar R and the electromagnetic conversion characteristics of the MR elements of the respective magnetic heads H are tested. More specifically, as shown in FIG. 3, electromagnet poles 10a, 10b are disposed respectively on the attachment surface Rb side and the ABS surface Rd of the row bar R to apply a magnetic field to the row bar R.

The electromagnetic conversion characteristics of the MR elements of the respective magnetic heads H are then tested by the testing circuit via the wires 12 connected to the connection terminals 6a, 6b of the magnetic heads H, the test terminals 4a, and the wires 4b. For example, the electromagnetic conversion characteristics of the MR elements are tested by detecting the changes in the magnetic resistance of the MR elements when a magnetic field is applied.

Note that the present invention is not limited to a construction where the heating step and the functional characteristic testing step are each carried out once only.

For example, it is possible to use a construction where the heating step and the functional characteristic testing step are repeatedly carried out alternately, such as a construction where the heating step is carried out to cause a predetermined simulated degradation over time of the MR elements, the functional characteristic testing step is then carried out to test the effects of such degradation over time, the heating step is then carried out again to cause further degradation of the MR elements, and the functional characteristic testing step is carried out again to test the effects of such degradation. The functional characteristic testing step is also not limited to being carried out after the heating step and as one example, the functional characteristic testing step may be carried out first, with the heating step and the functional characteristic testing step being carried out repeatedly thereafter. Also, the heating step and the functional characteristic testing step may be carried out simultaneously. That is, it is possible to use a construction where a magnetic field is applied to the row bar while the row bar is being heated to test the electromagnetic conversion characteristics of the row bar.

In this way, according to the present invention, there are no particular limitations on the temporal relationship between the heating step and the functional characteristic testing step and the number of iterations of each step, and both may be changed as appropriate in accordance with the content of the test.

According to the testing step in a method of manufacturing a magnetic head according to the present embodiment, the heating step and the functional characteristic testing step are carried out in a state where row bars R have been cut out from the wafer, so that compared to the conventional method where testing is carried out by incorporating a magnetic head in an HGA, it is possible to suppress the testing time and operation cost. In addition, since at least one surface of the row bar R in the lengthwise direction (in the described example, the two surfaces Rb, Rc) is held using a holding jig 2 made of metal with a lower thermal expansion coefficient than the row bar R, it becomes difficult for the row bar R to deform, and since the connection terminals 6a, 6b of the magnetic heads H are electrically connected via the wires 12, even if the row bar R (the magnetic heads H) deforms due to heat, the wires will move in accordance with the deformation of the row bar R and therefore problems such as poor electrical contact will not occur.

In particular, during the heating step, by heating the row bar R after placing the row bar R in contact with the heating plate 8 and sandwiching the row bar R between the holding jig 2 and the heating plate 8, it is possible to more favorably suppress deformation of the row bar R due to heat.

Also, a construction where the row bar R is heated by being placed in contact with the heating plate 8 can suppress the equipment cost compared to the conventional method where a constant temperature oven or the like is provided.

Also, since the formation surface Ra of the connection terminals 6a, 6b of the row bar R (the magnetic heads H) protrudes in parallel to the end surface 2a of the holding jig 2 on which the test terminals 4a are provided, the wires 12 can be connected easily in the wire bonding step within a parallel plane.

Also, since the test terminals 4a and the wires 4b for testing are provided on the flexible printed circuit board 4, it is possible to provide the test terminals 4a favorably on the holding jig 2. In addition, even if the flexible printed circuit board 4 deteriorates and/or wire bonding is carried out many times on the test terminals 4a resulting in a lack of space for bonding the wires 12, by replacing the flexible printed circuit board 4, it is possible to easily replace the test terminals 4a. When it is necessary to change the arrangement of the test terminals 4a in accordance with the specification of the magnetic heads H (the row bar R), this can be easily managed by replacing the flexible printed circuit board 4.

Note that the method of manufacturing according to the present invention is not limited to causing simulated degradation over time of MR elements by heating magnetic heads and testing the electromagnetic conversion characteristics of the MR elements, and so long as the object is to heat a magnetic head and test the functional characteristics of the magnetic head, it should be obvious that the method of manufacturing can be applied to all kinds of tests of magnetic heads.

What is claimed is:

1. A method of manufacturing a magnetic head including a testing step that heats the magnetic head and tests the functional characteristics of the magnetic head,
wherein the testing step comprises:
a row bar holding step of holding at least one surface in a lengthwise direction of a row bar cut out from a wafer using a holding jig with a lower thermal expansion coefficient than the row bar;
a wire bonding step of connecting, via wires, connection terminals of respective magnetic heads on the row bar and test terminals for electrically connecting the connection terminals for test purposes;
a heating step of heating the row bar; and
a functional characteristic testing step of testing functional characteristics of the respective magnetic heads via the test terminals and the wires.

2. A method of manufacturing a magnetic head according to claim 1,
wherein the row bar holding step holds the row bar on the holding jig so that a formation surface of the connection terminals on the row bar is exposed to one end surface of the holding jig and is substantially parallel to the end surface, and
the test terminals are provided on the end surface.

3. A method of manufacturing a magnetic head according to claim 2,
wherein the test terminals are provided on a flexible printed circuit board disposed across an outer surface of the holding jig.

4. A method of manufacturing a magnetic head according to claim 2,
wherein a cutaway part, which matches an outer shape of the row bar, is formed in an edge part of the end surface of the holding jig, and
the row bar holding step holds the row bar inside the cutaway part.

5. A method of manufacturing a magnetic head according to claim 1,
wherein the row bar holding step holds the row bar on the holding jig by adhesion.

6. A method of manufacturing a magnetic head according to claim 1,
wherein the holding jig is made of metal.

7. A method of manufacturing a magnetic head according to claim 1,
wherein the heating step is carried out by placing an opposite surface to the one surface in a lengthwise direction of a row bar in contact with a heating plate and heating the heating plate.

8. A method of manufacturing a magnetic head according to claim 1,
wherein in the functional characteristic testing step, a magnetic field is applied to the row bar and electromagnetic conversion characteristics of MR elements of the respective magnetic heads are tested.
